(19) United States
(12) Patent Application Publication
(10) Pub. No.: US 2024/0112955 A1
(43) Pub. Date: Apr. 4, 2024

(54) MANUFACTURING METHOD OF CHIPS

(71) Applicant: DISCO CORPORATION, Tokyo (JP)

(72) Inventor: Yu ZHAO, Tokyo (JP)

(21) Appl. No.: 18/467,860

(22) Filed: Sep. 15, 2023

(30) Foreign Application Priority Data
Oct. 4, 2022 (JP) 2022-159900

(51) Int. Cl. H01L 21/78; H01L 21/3065

(52) U.S. Cl. CPC H01L 21/78; H01L 21/30655; H01L 21/3081

(57) ABSTRACT

Provided is a manufacturing method of a plurality of chips by dividing a workpiece that is defined into a plurality of regions by scribe lines. The manufacturing method includes the following steps of forming a mask by supplying a plasmatic deposition gas to a side of a front surface or a side of a back surface of the workpiece, forming cut grooves, with the mask being removed along the scribe lines, by causing a cutting blade to cut into the workpiece at a predetermined cut-in depth along the scribe lines on a side of the surface on which the mask has been formed, and then removing the workpiece along the scribe lines to divide the workpiece into the chips by applying plasma etching to the workpiece while supplying a plasmatic etching gas to the side of the surface of the workpiece in which the cut grooves have been formed.

### BACKGROUND OF THE INVENTION

### Field of the Invention

The present invention relates to a manufacturing method of a plurality of chips, in which the chips are manufactured by dividing a workpiece.

### Description of the Related Art

In a manufacturing process of device chips, a wafer is used with respective devices formed in a plurality of regions defined by a plurality of scribe lines (streets) arrayed in a grid pattern. By dividing this wafer along the scribe lines, a plurality of device chips with the respective devices included therein are obtained. These device chips are incorporated in various pieces of electronic equipment such as mobile phones or personal computers.

For the division of a wafer, a cutting apparatus that cuts the workpiece with an annular cutting blade, a laser processing apparatus that applies laser processing to the workpiece, or the like is used. In recent years, development of processing that divides a wafer by applying plasma etching and is called plasma dicing is also under way. In plasma dicing, a mask that is patterned such that scribe lines are exposed is first formed on a wafer. An etching gas in a plasma state is then supplied to the wafer through the mask, so that plasma etching is applied along the scribe lines to divide the wafer.

A mask for plasma etching is formed by patterning, for example, a photoresist along scribe lines. A method that forms a mask with a laser processing apparatus has also been proposed to achieve simplification of processing steps and cost reduction. Disclosed in JP 2016-207737A, for example, is a method for forming an etching mask, with scribe lines exposed, by forming a water-soluble protective film on a wafer and then emitting a laser beam to the water-soluble protective film along the scribe lines.

### SUMMARY OF THE INVENTION

When applying plasma etching to a workpiece such as a wafer, a photoresist or a water-soluble protective film is formed as a mask on the wafer, as described above. However, the formation of the mask with the photoresist needs steps for application, exposure, and development of the resist, thereby taking time and effort for the formation of the mask. On the other hand, the use of the method that performs the patterning of the water-soluble protective film by the irradiation of the laser beam can form the mask through a smaller number of steps compared with the use of the photoresist. Moreover, the laser processing apparatus allows to easily change the irradiation conditions for the laser beam, so that even if a workpiece to which plasma etching is to be applied is changed, design changes can be promptly made to the mask according to the kind of the changed workpiece.

When performing the patterning of the water-soluble protective film by the laser processing apparatus, however, elaborate laser processing that uses a short pulsed laser is needed such that heat produced by the irradiation of a laser beam does not cause deleterious effects on the workpiece. This increases costs required for the implementation and operation of the laser processing apparatus, and therefore prevents the cost reduction of plasma etching.

With the foregoing problems in view, the present invention has as an object thereof the provision of a manufacturing method of chips, which can reduce costs of plasma etching.

In accordance with an aspect of the present invention, there is provided a manufacturing method of a plurality of chips, the method manufacturing the chips by dividing a workpiece that is defined into a plurality of regions by scribe lines, including a mask forming step of forming a mask by supplying a plasmatic deposition gas to a side of a front surface or a side of a back surface of the workpiece, a cutting step of forming cut grooves, with the mask being removed along the scribe lines, by causing a cutting blade to cut into the workpiece at a predetermined cut-in depth along the scribe lines on the side of a surface on which the mask has been formed, and a plasma etching step of removing the workpiece along the scribe lines to divide the workpiece into the chips by applying plasma etching to the workpiece while supplying a plasmatic etching gas to the side of the surface of the workpiece in which the cut grooves have been formed.

Preferably, the cutting blade may have a tip end portion having a width tapering toward a tip end, and in the cutting step, the cutting blade may be caused to cut into the mask such that only the tip end portion comes into contact with the mask. Also preferably, in the cutting step, the cut-in depth of the cutting blade may be set to smaller than 10 μm.

Also preferably, in the plasma etching step, the workpiece may be divided into the chips along the scribe lines by repeating a protective film application substep of applying a protective film to the cut grooves by supplying a plasmatic deposition gas to the side of the surface of the workpiece in which the cut grooves have been formed, an anisotropic etching substep of, after the protective film application substep, removing portions of the protective film covering corresponding bottoms of the cut grooves, through anisotropic plasma etching of the protective film by supplying a plasmatic gas for anisotropic etching to the cut grooves, and an isotropic etching substep of, after the anisotropic etching substep, subjecting the bottoms of the cut grooves to isotropic plasma etching by supplying a plasmatic gas for isotropic etching to the cut grooves. Also preferably, the manufacturing method may further include a mask removal step of removing the mask after the plasma etching step.

In the manufacturing method for chips according to the aspect of the present invention, the patterning of the mask formed on the workpiece is performed through the removal of the mask along the scribe lines by causing the cutting blade to cut into the mask. Accordingly, it is possible to form a mask for plasma etching with an inexpensive cutting machine instead of a costly laser processing apparatus or the like, thereby reducing the costs of plasma etching.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1A is a perspective view depicting a workpiece usable in a manufacturing method for chips according to an embodiment of an aspect of the present invention;

FIG. 1B is a fragmentary cross-sectional view depicting the workpiece of FIG. 1A;

FIG. 2 is a partial cross-sectional front view depicting a plasma processing apparatus for use in the manufacturing method according to the embodiment;

FIG. 3 is a flow chart illustrating the manufacturing method of chips according to the embodiment;

FIG. 4A is a fragmentary partial cross-sectional front view depicting the workpiece in a mask forming step of the manufacturing method according to the embodiment;

FIG. 4B is a fragmentary cross-sectional view depicting the workpiece after the mask forming step of FIG. 4A;

FIG. 5A is a fragmentary partial cross-sectional front view depicting the workpiece in a cutting step of the manufacturing method according to the embodiment;

FIG. 5B is a fragmentary partial cross-sectional front view depicting a tip end portion of a cutting blade for use in the cutting step of FIG. 5A;

FIG. 5C is a fragmentary partial cross-sectional front view depicting a modification of the tip end portion of the cutting blade in FIG. 5B;

FIG. 6 is a fragmentary cross-sectional view depicting the workpiece after the cutting step of FIG. 5A;

FIG. 7 is a flow chart illustrating an example of a plasma etching step in the manufacturing method according to the embodiment;

FIG. 8A is a fragmentary cross-sectional view depicting the workpiece in a protective film application substep of the plasma etching step of FIG. 7;

FIG. 8B is a fragmentary cross-sectional view depicting the workpiece in an anisotropic etching substep of the plasma etching step of FIG. 7;

FIG. 8C is a fragmentary cross-sectional view depicting the workpiece in an isotropic etching substep of the plasma etching step of FIG. 7;

FIG. 9 is a fragmentary cross-sectional view depicting the workpiece after the plasma etching step illustrated in FIG. 7;

FIG. 10A is a micrograph depicting a side of an upper surface of a wafer after formation of a mask and cut grooves in an Example of the embodiment;

FIG. 10B is a micrograph depicting a cross-section of the wafer after the formation of the mask and cut grooves in the Example;

FIG. 11A is a micrograph depicting a cross-section of the wafer after plasma etching in the Example; and

FIG. 11B is a micrograph depicting on an enlarged scale a cut groove formed in the wafer in the Example.

### DETAILED DESCRIPTION OF THE PREFERRED EMBODIMENT

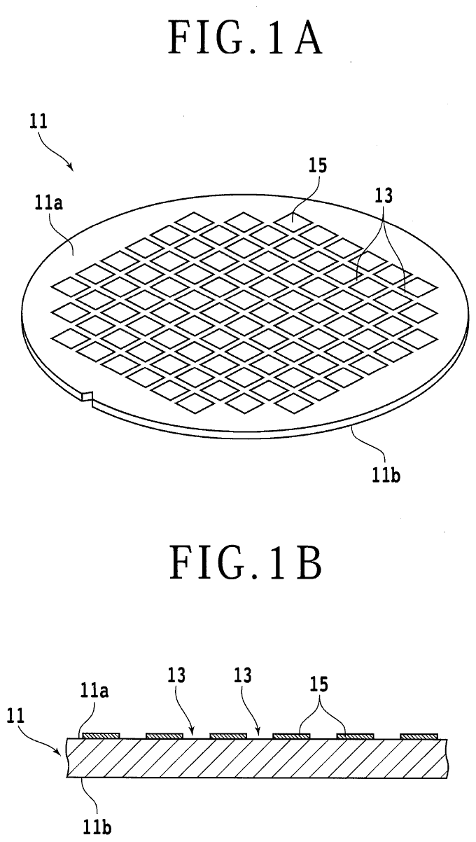

With reference to the attached drawings, an embodiment of an aspect of the present invention will hereinafter be described. A description will first be made of a configuration example of a workpiece usable in a manufacturing method for chips according to this embodiment. FIG. 1A is a perspective view depicting a workpiece 11, and FIG. 1B is a cross-sectional view depicting the workpiece 11.

The workpiece 11 is, for example, a disk-shaped wafer made from a semiconductor material such as a single crystal silicon, and includes a front surface (first surface) 11a and a back surface (second surface) 11b, which are substantially parallel to each other. The workpiece 11 is defined into a plurality of rectangular regions by a plurality of scribe lines (streets) 13 arrayed and set such that they intersect. On a side of the front surface 11a of the regions defined by the scribed lines 13, devices 15 such as integrated circuits (ICs), large scale integrations (LSIs), light emitting diodes (LEDs), or micro electro mechanical systems (MEMS) devices are formed individually. By dividing the workpiece 11 along the scribe lines 13, a plurality of chips (device chips) each including the device 15 are manufactured. However, no limitations are imposed on the material, shape, structure, size, and the like of the workpiece 11. The workpiece 11 may be, for example, a wafer (substrate) made from a semiconductor (GaAs, InP, GaN, SiC, or the like) other than silicon, sapphire, a glass, a ceramic, a resin, a metal, or the like. No limitations are imposed either on the kind, number, shape, structure, size, arrangement, and the like of the devices 15, and no devices 15 may be formed on the workpiece 11.

In this embodiment, the workpiece 11 is divided along the scribe lines 13 by applying plasma etching to the workpiece 11 (plasma dicing). For the plasma etching of the workpiece 11, a plasma processing apparatus is used to supply a plasmatic gas to the workpiece 11.

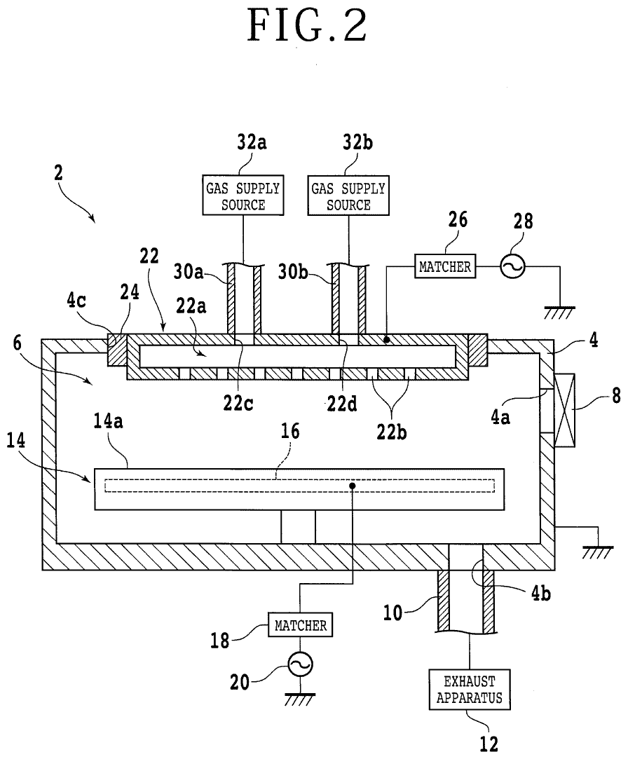

FIG. 2 is a partial cross-sectional front view depicting a plasma processing apparatus 2. The plasma processing apparatus 2 includes a chamber 4, in which the workpiece 11 is to be placed. The chamber 4 is made from an electrically conductive material such as a metal and is grounded. An inside of the chamber 4 corresponds to a processing space 6, in which plasma processing for the workpiece 11 is to be performed.

In a side wall of the chamber 4, an opening 4a is disposed to transfer the workpiece 11. On an outer side of the opening 4a, a gate (openable door) 8 is disposed to open or close the opening 4a. A moving mechanism (not depicted) such as an air cylinder is coupled with the gate 8, and the moving mechanism causes the gate 8 to be raised or lowered along the side wall of the chamber 4. By lowering the gate 8 and exposing the opening 4a, the workpiece 11 can be loaded into the processing space 6 through the opening 4a, or can be unloaded from the processing space 6 through the opening 4a. Further, the processing space 6 is hermetically closed by raising the gate 8 and closing the opening 4a.

Through a bottom wall of the chamber 4, an opening 4b is disposed to communicate the inside and an outside of the chamber 4 with each other. The opening 4b is communicated to an exhaust apparatus 12 such as a vacuum pump via a piping 10. When the exhaust apparatus 12 is activated with the processing space 6 kept hermetically closed, the processing space 6 is exhausted and depressurized.

In the processing space 6, a holding table (chuck table) 14 is disposed to hold the workpiece 11. The holding table 14 has an upper surface, which is a planar surface substantially parallel to a horizontal plane and constitutes a holding surface 14a on which the workpiece 11 is to be held. An electrostatic chuck that holds the workpiece 11 by an electric force can be used as the holding table 14. The holding table 14 is made, for example, from a dielectric material such as a ceramic, and a disk-shaped electrode 16 is disposed inside the holding table 14. The electrode 16 is arranged substantially in parallel to the holding surface 14a, and is connected to a radio frequency power supply 20 via a matcher 18. It is to be noted that a cooling path (not depicted) may also be disposed inside the holding table 14 to allow flowing of a coolant such as water. The holding table 14 is cooled by allowing the coolant to flow through the cooling path.

Above the holding table 14, a gas ejection head 22 is disposed. The gas ejection head 22 is made from an electrically conductive material such as a metal, and is inserted in an opening 4c disposed through a top wall of the chamber 4. It is to be noted that an annular bearing 24 made from an electrically insulating material is disposed between the top wall of the chamber 4 and the gas ejection head 22. The bearing 24 is disposed so as to surround the gas ejection head 22, and insulates the chamber 4 and the gas ejection head 22.

The gas ejection head 22 is connected to a radio frequency power supply 28 via a matcher 26. To the gas ejection head 22, a lift mechanism (not depicted) is connected to raise or lower the gas ejection head 22 in a vertical direction. The distance between the holding table 14 and the gas ejection head 22 is adjusted by raising or lowering the gas ejection head 22 with the lift mechanism.

Disposed inside the gas ejection head 22 is a gas diffusion space 22a to which two gases of different types for plasma processing are supplied. On a side of a lower surface of the gas ejection head 22, a plurality of gas supply paths 22b are disposed, communicating the processing space 6 of the chamber 4 and the gas diffusion space 22a to each other. On a side of an upper surface of the gas ejection head 22, a pair of gas supply paths 22c and 22d is disposed. The gas supply path 22c is connected to a gas supply source 32a via a piping 30a, while the gas supply path 22d is connected to a gas supply source 32b via a piping 30b. The gas supply source 32a supplies one of the two gases of different types for plasma processing to the gas diffusion space 22a via the piping 30a and the gas supply path 22c. Similarly, the gas supply source 32b supplies the other one of the two gases of different types for plasma processing to the gas diffusion space 22a via the piping 30b and the gas supply path 22d. As a consequence, these two gases of different types are mixed in the gas diffusion space 22a. It is to be noted that FIG. 2 depicts a configuration in which the two gases of different types for plasma processing are supplied to the gas ejection head 22 from the two gas supply sources 32a and 32b. However, the number of gas supply sources connected to the gas ejection head 22 may be 1, or 3 or more.

When applying plasma processing to the workpiece 11 using the plasma processing apparatus 2, the gate 8 is first lowered, so that the opening 4a is exposed. The workpiece 11 is then loaded by a transfer mechanism (not depicted) into the processing space 6 through the opening 4a, and is arranged on the holding surface 14a of the holding table 14. It is to be noted that, upon loading of the workpiece 11, the gas ejection head 22 may preferably be raised in advance to widen the distance between the holding table 14 and the gas ejection head 22.

The gate 8 is next raised to close the opening 4a, whereby the processing space 6 is hermetically closed. A predetermined voltage is then applied to the electrode 16 by the radio frequency power supply 20. This causes dielectric polarization to occur on a side of the holding surface 14a of the holding table 14, and an electrostatic attraction force acts between the holding surface 14a and the workpiece 11. As a result, the workpiece 11 is held under suction on the holding surface 14a. Further, the height of the gas ejection head 22 is adjusted such that the holding table 14 and the gas ejection head 22 are arranged at a distance suited for plasma processing. Furthermore, the exhaust apparatus 12 is activated, and the processing space 6 is depressurized.

Both or one or the other of the two gases of different types for plasma processing are/is next supplied from the gas supply source 32a and/or the gas supply source 32b to the gas diffusion space 22a. Further, radio frequency power is applied by the radio frequency power supply 28 to the gas ejection head 22. As a result, a gas or a gas mixture in the gas diffusion space 22a is transformed into a plasma, and the resulting plasmatic gas is supplied to and spread in the processing space 6 through the gas supply paths 22b. As a consequence, the plasmatic gas is supplied to the workpiece 11 on the holding table 14, so that predetermined plasma processing (deposition processing, etching treatment, or the like) is applied to the workpiece 11.

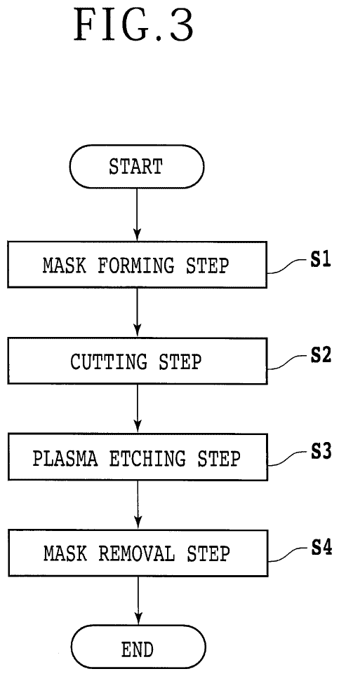

A description will next be made regarding the manufacturing method for chips according to this embodiment. In this embodiment, the workpiece 11 (see FIGS. 1A and 1B) is divided into a plurality of chips by applying plasma processing to the workpiece 11 by use of the plasma processing apparatus 2 (see FIG. 2). FIG. 3 is a flow chart illustrating the manufacturing method for chips according to the embodiment.

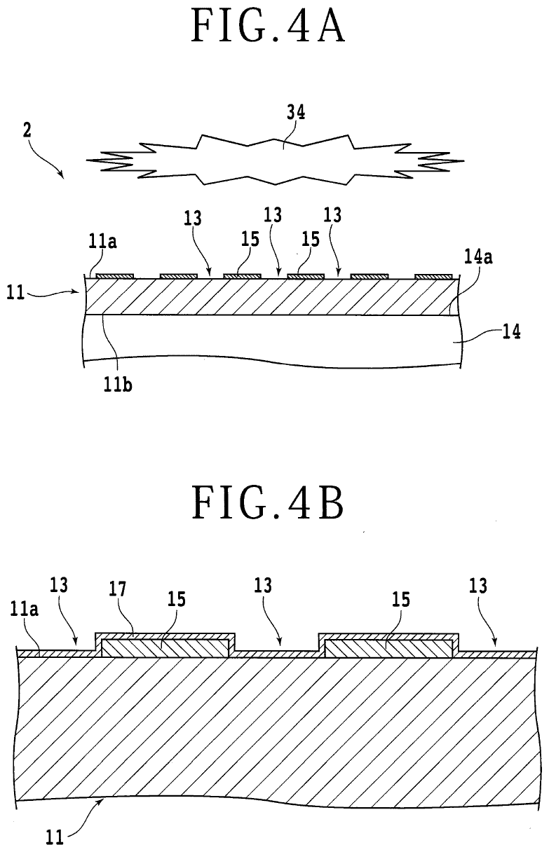

When dividing the workpiece 11, a mask is first formed by supplying a plasmatic deposition gas to the side of the front surface 11a or a side of the back surface 11b (mask forming step S1). It is to be noted that a description will hereinafter be made taking as a representative example a case in which the mask is to be formed on the side of the front surface 11a of the workpiece 11, but the mask may be formed on the side of the back surface 11b of the workpiece 11. FIG. 4A is a fragmentary partial cross-sectional front view depicting the workpiece 11 in the mask forming step S1. In the mask forming step S1, the mask is formed on the workpiece 11 by the plasma processing apparatus 2.

Described specifically, the workpiece 11 is first held on the holding surface 14a of the holding table 14 such that the workpiece 11 is upwardly exposed on the side of the surface on which the mask is to be formed (on the side of the front surface 11a) and the workpiece 11 faces the holding surface 14a on the side of the opposite surface (the side of the back surface 11b). A protective film forming gas is then supplied to the gas diffusion space 22a (see FIG. 2) of the gas ejection head 22 and at the same time, radio frequency power is applied to the gas ejection head 22. As a consequence, the gas in the gas diffusion space 22a is transformed into a plasma, and a gas 34 (deposition gas) that is in a plasma state and contains ions and radicals is produced. If this carbon-containing deposition gas 34 (a C₄F₈-containing gas, a CH₄-containing gas, or the like) is supplied to the workpiece 11, a film that contains carbon is formed on the workpiece 11. For example, the C₄F₈-containing gas supplied from the gas supply source 32a and the Ar gas supplied from the gas supply source 32b are mixed, and the deposition gas 34 in the plasma state is produced. The deposition gas 34 is then supplied to the workpiece 11, and CF radicals contained in the deposition gas 34 deposit on the side of the front surface 11a of the workpiece 11. As a consequence, an insulating film with carbon fluoride contained therein (fluorocarbon film) is formed on the side of the front surface 11a of the workpiece 11. This film with carbon fluoride contained therein is used as the mask in plasma etching.

FIG. 4B is a fragmentary cross-sectional view depicting the workpiece 11 after the mask forming step S1. CF radicals are deposited, for example, on the side of the front surface 11a of the workpiece 11, so that a mask 17 (a film with carbon fluoride contained therein) is formed on the side of the front surface 11a of the workpiece 11. It is to be noted that the CF radicals uniformly deposit on the front surface 11a of the workpiece 11 and on surfaces of the devices 15. As a result, the mask 17 having a uniform thickness, to which the shapes of the front surface 11a of the workpiece 11 and the surfaces of the devices 15 are reflected, is formed. The thickness of the mask 17 is appropriately set taking into consideration the below-mentioned conditions and the like for plasma etching. However, the thinner the mask 17, the shorter the deposition time. It is therefore preferred to form the mask 17 to be thin within a range that it functions as a mask for plasma etching. For example, the thickness of the mask 17 is smaller than 10 μm, preferably smaller than 5 μm.

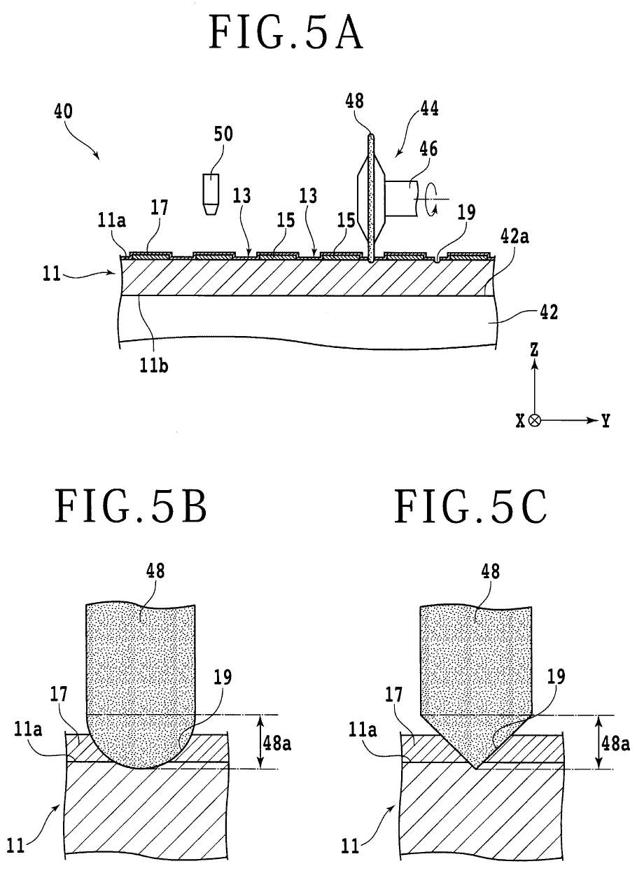

While removing the mask 17 along the scribe lines 13, cut grooves are next formed by causing an annular cutting blade 48 (see FIG. 5A) to cut to a predetermined cut-in depth into the workpiece 11 on the side of a surface on which the mask 17 is formed (on the side of the front surface 11a) (cutting step S2). FIG. 5A is a fragmentary partial cross-sectional front view depicting the workpiece 11 in the cutting step S2. In the cutting step S2, the mask 17 is cut by use of a cutting apparatus 40. It is to be noted that, in FIG. 5A, an X-axis direction (processing feed direction, first horizontal direction) and a Y-axis direction (indexing feed direction, second horizontal direction) are perpendicular to each other. On the other hand, a Z-axis direction (cut-in depth direction, height direction, vertical direction, up-down direction) is perpendicular to the X-axis direction and Y-axis direction.

The cutting apparatus 40 has a holding table (chuck table) 42 that holds the workpiece 11. The holding table 42 has an upper surface, which is a planar surface substantially parallel to a horizontal plane (XY plane), and constitutes a circular holding surface 42a that holds the workpiece 11. The holding surface 42a is communicated to a suction source (not depicted) such as an ejector via a flow passage (not depicted) formed inside the holding table 42, a valve (not depicted), and the like.

The holding table 42 has a moving unit (not depicted) and a rotary drive source (not depicted) coupled therewith. The moving unit is configured, for example, with a ball screw type moving mechanism, and moves the holding table 42 along the X-axis direction. On the other hand, the rotary drive source is configured with a motor or the like, and rotates the holding table 42 about an axis of rotation that is substantially parallel to the Z-axis direction.

The cutting apparatus 40 also includes a cutting unit 44 that cuts the workpiece 11. The cutting unit 44 is arranged above the holding table 42, and includes a cylindrical spindle 46 arranged along the Y-axis direction. On a distal end portion (one end portion) of the spindle 46, the annular cutting blade 48 is mounted. A proximal end portion (the other end portion) of the spindle 46, on the other hand, has a rotary drive source (not depicted) such as a motor is coupled therewith. The cutting blade 48 is rotated about an axis of rotation, which is substantially parallel to the Y-axis direction, by power transmitted from the rotary drive source via the spindle 46. As the cutting blade 48, a cutting blade of, for example, the hub type (hub blade) is used. The hub blade includes an annular hub base made from a metal or the like, and an annular cutting edge formed along an outer peripheral edge of the hub base. The cutting edge of the hub blade is configured with an electroformed grinding stone which includes abrasive grits of diamond or the like and a binding material such as a nickel plating layer that fixedly secures the abrasive grits. However, a washer type cutting blade (washer blade) can also be used as the cutting blade 48. The washer blade is configured with only an annular cutting edge, which includes abrasive grits of diamond or the like and a binding material that is formed of a metal, a ceramic, a resin, or the like and fixedly secures the abrasive grits.

The cutting unit 44 has a moving unit (not depicted) coupled therewith. The moving unit is configured, for example, with a ball screw type moving mechanism, and moves the cutting unit 44 in the Y-axis direction and the Z-axis direction. The position in the indexing direction of the cutting blade 48, the cut-in depth of the cutting blade 48 into the workpiece 11, and the like are adjusted by the moving mechanism.

When cutting the workpiece 11 by the cutting apparatus 40, the workpiece 11 is first held on the holding table 42. Described specifically, the workpiece 11 is arranged on the holding table 42 such that the workpiece 11 is upwardly directed on the side of the surface on which the mask 17 is formed (on the side of the front surface 11a) and faces the holding surface 42a on the side of the opposite surface (on the side of the back surface 11b). When a suction force (negative pressure) of the suction source is allowed to act on the holding surface 42a with the workpiece 11 arranged as described above, the workpiece 11 is held under suction on the holding table 42.

The holding table 42 is next rotated to bring the length direction of a predetermined one of the scribe lines 13 into alignment with the X-axis direction. Further, the position in the Y-axis direction of the cutting unit 44 is adjusted such that the positions in the Y-axis direction of the cutting blade 48 and the predetermined one scribe line 13 are brought into coincidence with each other. Furthermore, the height position (the position in the Z-axis direction) of the cutting unit 44 is adjusted such that the cutting blade 48 is positioned at a lower end thereof slightly lower than the front surface 11a of the workpiece 11 (a lower surface of the mask 17). With the cutting blade 48 kept rotating, the holding table 42 is then moved along the X-axis direction. As a consequence, the holding table 42 and the cutting blade 48 are relatively moved along the X-axis direction, and the cutting blade 48 is caused to cut into the workpiece 11 and the mask 17 along the predetermine one scribe line 13. The difference in height position between a surface (upper surface) of the mask 17 and a tip end (lower end) of the cutting blade 48 at this time corresponds to the cut-in depth of the cutting blade 48. The cut-in depth of the cutting blade 48 is set equal to or greater than the thickness of the mask 17.

When cutting the workpiece 11 and the mask 17 by the cutting blade 48, a liquid (cutting fluid) such as pure water is supplied to the cutting blade 48. As a consequence, the cutting blade 48 is cooled, and at the same time, debris occurring by cutting processing is washed away.

When the cutting blade 48 is caused to cut in as described above, cut grooves 19 are formed along the scribe lines 13 in the workpiece 11 on the side of the front surface 11a and also in the mask 17. The cut grooves 19 are formed so as to split the mask 17 and extend to the front surface 11a of the workpiece 11.

It is to be noted that the cutting blade 48 preferably has a tip end portion 48a (see FIG. 5B) of a width tapering toward a tip end. In the cutting step S2, the cutting blade 48 is preferably caused to cut into the mask 17 so as to come into contact with the mask 17 at only the tip end portion 48a thereof.

FIG. 5B is a fragmentary partial cross-sectional front view depicting the tip end portion 48a of the cutting blade 48. The cutting blade 48 has the tip end portion 48a having a surface formed in an arc shape extending from one side toward the other side thereof. Described specifically, the surface of the tip end portion 48a is curved (has a rounded shape), and the tip end portion 48a is formed such that its width becomes gradually narrower toward the tip end (lower end). FIG. 5C is a fragmentary partial cross-sectional front view depicting a modification of the tip end portion 48a of the cutting blade 48. As depicted in FIG. 5C, the tip end portion 48a of the cutting blade 48 may include a pair of planar side surfaces formed so as to be inclined with respect to a radial direction of the cutting blade 48. In this case, the surface of the tip end portion 48a has a V-shape as seen in a cross-section, and the tip end portion 48a is formed such that its width becomes gradually narrower toward the tip end (lower end).

In the cutting step S2, the cutting blade 48 is caused to cut into the mask 17 such that only the tip end portion 48a (tapered area) of the cutting blade 48 comes into contact with the mask 17. As a consequence, an area of the mask 17, in which the cutting blade 48 comes into contact with the mask 17, is cut such that the mask 17 is pressed toward the side of the front surface 11a of the workpiece 11 by the surface of the tip end portion 48a of the cutting blade 48. As a result, peeling of the mask 17 due to the contact between the cutting blade 48 and the mask 17 is hardly generated, even if the cutting blade 48 which is rotating at high speed is caused to cut into the mask 17.

The mask 17 is then removed along all the scribe lines 13 by repeating similar procedures. As a result, the workpiece 11 is obtained with the cut grooves 19 formed in a grid pattern along the scribed lines 13.

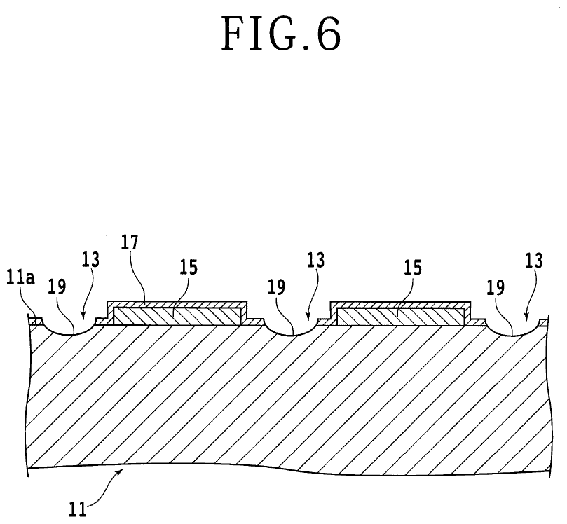

FIG. 6 is a fragmentary cross-sectional view depicting the workpiece 11 after the cutting step S2. The cut grooves 19 are formed in regions of the mask 17, where the mask 17 overlaps the scribe lines 13, so that the cut grooves 19 reach the front surface 11a of the workpiece 11. As a result, the mask 17 is split along the scribe lines 13, and at the same time, portions (lower end portions) of the cut grooves 19 are formed in the workpiece 11 on the side of the front surface 11a, so that the front surface 11a of the workpiece 11 is exposed along the scribe lines 13. It is to be noted that the shape of the tip end portion 48a of the cutting blade 48 is reflected in the profile of the cut grooves 19. Described specifically, if the tip end portion 48a of the cutting blade 48 has the rounded shape (see FIG. 5B), the cut grooves 19 are formed in a curved shape. If the tip end portion 48a of the cutting blade 48 has the V-shape (see FIG. 5C), on the other hand, the cut grooves 19 are formed each including a pair of inner walls inclined with respect to the front surface 11a of the workpiece 11 and also with the surface of the mask 17.

The cut-in depth of the cutting blade 48 in the cutting step S2 is appropriately set according to the thickness of the mask 17, the length of the tip end portion 48a of the cutting blade 48, and the like. It is however to be noted that the tip end portion 48a (tapered area) of the cutting blade 48 is often formed especially in a range of approximately 10 μm from the tip end of the cutting blade 48. It is therefore preferred to set the cut-in depth of the cutting blade 48 to smaller than 10 μm.

In the cutting step S2, the cut grooves 19 may be formed while adjusting the height position of the cutting blade 48 according to the height position of the surface of the mask 17. Described specifically, the cutting apparatus 40 may include a measurement unit 50 to measure displacements of the height position of the surface of an object, specifically the mask 17 as depicted in FIG. 5A. The measurement unit 50 is configured, for example, with a non-contact displacement meter such as a laser displacement meter, and measures the height position of the surface of the mask 17. When the workpiece 11 is held on the holding table 42, the height position of the surface of the mask 17 in each area where the mask 17 is to be cut by the cutting blade 48 (the area that overlaps each scribe line 13) is measured by the measurement unit 50. When causing the cutting blade 48 to cut into the workpiece 11 and the mask 17 along each scribe line 13, the height position of the cutting blade 48 is sequentially adjusted according to the height position of the surface of the mask 17 as measured by the measurement unit 50 such that the cut-in depth of the cutting blade 48 remains constant.

By adjusting the cut-in depth of the cutting blade 48 according to the height position of the surface of the actual mask 17 as described above, the cut-in depth of the cutting blade 48 can be maintained constant even if there are variations in the height position of the surface of the mask 17. This ensures that the mask 17 can be split without causing the cutting blade 48 to cut into the workpiece 11 unnecessarily. It is to be noted that, if thickness variations of the workpiece 11 and the mask 17 are small, the height position of the holding surface 42a (see FIG. 5A) of the holding table 42 may be measured by the measurement unit 50. In this case, the height position of the cutting blade 48 is sequentially adjusted according to the height position of the holding surface 42a measured by the measurement unit 50 when causing the cutting blade 48 to cut into the workpiece 11 and the mask 17 along each scribe line 13. This can maintain the cut-in depth of the cutting blade 48 constant even if there are irregularities on the holding surface 42a.

The workpiece 11 is next removed along the scribe lines 13 and divided into the chips by applying plasma etching to the workpiece 11 (plasma etching step S3). In the plasma etching step S3, a plasmatic etching gas is supplied to the side of the surface (the side of the front surface 11a, the side of the mask 17) of the workpiece 11, where the cut grooves 19 have been formed in the workpiece 11, thereby applying plasma etching to the workpiece 11.

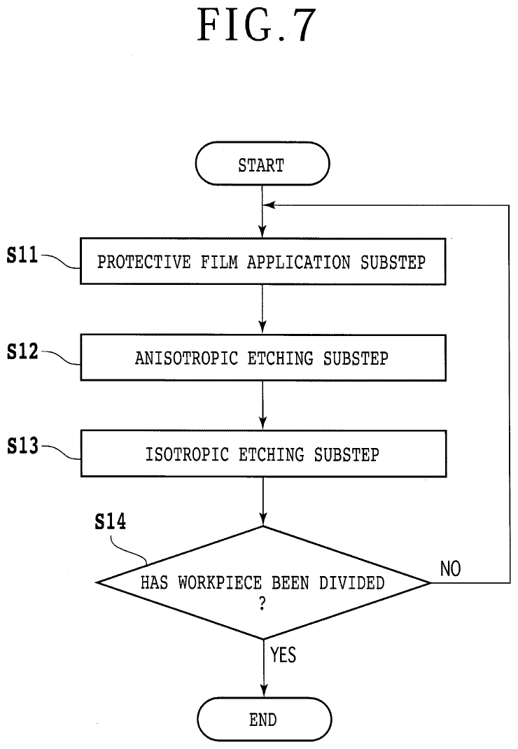

FIG. 7 is a flow chart illustrating an example of the plasma etching step S3. In the plasma etching step S3, the workpiece 11 is divided along the scribe lines 13 by use of, for example, the Bosch process to allow the cut grooves 19 to extend to the surface (back surface 11b) on a side opposite to the surface, on which the mask 17 is formed, of the workpiece 11. Described specifically, the cut grooves 19 are allowed to reach the back surface 11b of the workpiece 11 by repeating work that etches the bottoms of the cut grooves 19 by performing a protective film application substep S11, an anisotropic etching substep S12, and an isotropic etching substep S13 in this order. The plasma processing apparatus 2 depicted in FIG. 2 can be used for the plasma etching.

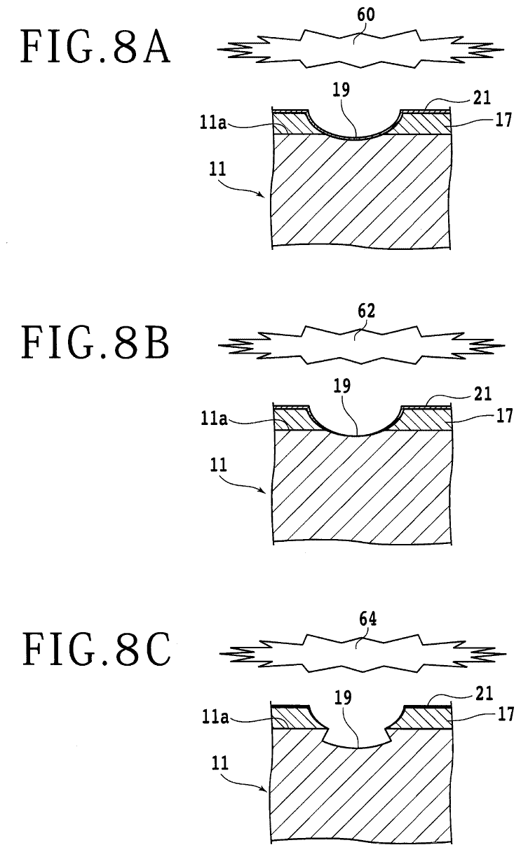

FIG. 8A is a fragmentary cross-sectional view depicting the workpiece 11 in the protective film application substep S11. In the protective film application substep S11, a protective film 21 is applied to the cut grooves 19 by supplying a plasmatic deposition gas 60 to the side of the surface (the side of the front surface 11a, the side of the mask 17) of the workpiece 11, where the cut grooves 19 have been formed.

Described specifically, the workpiece 11 is held on the holding surface 14a (see FIG. 2) of the holding table 14 such that the workpiece 11 is upwardly exposed on the side of the front surface 11a (on the side of the mask 17, on the side of the cut grooves 19), and on the side of the back surface 11b, faces the holding surface 14a. A deposition gas, specifically a protective film forming gas is then supplied to the gas diffusion space 22a (see FIG. 2) of the gas ejection head 22, and at the same time, radio frequency power is applied to the gas ejection head 22. As a consequence, the plasmatic protective film forming gas 60 is supplied to the side of the front surface 11a of the workpiece 11. When the protective film forming gas 60 is supplied to the workpiece 11, ions and radicals which are both contained in the protective film forming gas 60 deposit on the mask 17, and at the same time, enter the cut grooves 19 and deposit on the inner walls of the cut grooves 19. As a result, the protective film 21 is formed on the surface of the mask 17 and the inner walls of the cut grooves 19, whereby the protective film 21 is applied to the cut grooves 19. For example, in the gas diffusion space 22a (see FIG. 2), the C₄F₈-containing gas supplied from the gas supply source 32a and the Ar gas supplied from the gas supply source 32b are mixed and are transformed into a plasma. In this case, CF radicals contained in the protective film forming gas 60 deposit on the side of the front surface 11a of the workpiece 11, whereby the insulating protective film 21 with carbon fluoride contained therein is formed on the surface of the mask 17 and the inner walls of the cut grooves 19. For example, the supply time of the protective film forming gas 60 is set to six seconds or longer and eight seconds or shorter, and the protective film 21 is formed to have a thickness of 10 nm or smaller.

FIG. 8B is a fragmentary cross-sectional view depicting the workpiece 11 in the anisotropic etching substep S12. In the anisotropic etching substep S12, the protective film 21 applied to the bottoms of the cut grooves 19 is removed through anisotropic plasma etching of the protective film 21 resulting from supplying a plasmatic gas 62 for anisotropic etching to the cut grooves 19.

Described specifically, a gas mixture 62 for anisotropic etching is supplied to the gas diffusion space 22a (see FIG. 2) of the gas ejection head 22. For example, a fluorinated gas (CF₄, SF₆, or the like) supplied from the gas supply source 32a and an inert gas (He, Ar, or the like) supplied from the gas supply source 32b are mixed into the gas mixture 62 for anisotropic etching in the gas diffusion space 22a. Respective radio frequency powers are then applied to the electrode 16 (see FIG. 2) and the gas ejection head 22. As a consequence, the gas mixture 62 for anisotropic etching in the gas diffusion space 22a is transformed into a plasma, and the resulting plasmatic etching gas 62 for anisotropic etching is accelerated toward the holding table 14, so that anisotropic plasma etching is applied to the workpiece 11. When this anisotropic plasma etching is continued for a certain period of time (for example, approximately three seconds), portions of the protective film 21 covering the bottoms of the cut grooves 19 are removed, and the bottoms of the cut grooves 19 are hence exposed, with remaining portions of the protective film 21 covering the upper ends of the cut grooves 19 being left.

FIG. 8C is a fragmentary cross-sectional view depicting the workpiece 11 in the isotropic etching substep S13. In the isotropic etching substep S13, the bottoms of the cut grooves 19 are isotropically subjected to plasma etching by supplying a plasmatic gas 64 for isotropic etching to the cut grooves 19.

Described specifically, a gas mixture 64 for isotropic etching is supplied to the gas diffusion space 22a (see FIG. 2) of the gas ejection head 22. In a case in which the workpiece 11 is a single crystal silicon wafer, for example, a fluorinated gas (CF₄, SF₆, or the like) supplied from the gas supply source 32a and an inert gas (He, Ar, or the like) supplied from the gas supply source 32b are mixed into the gas mixture 64 for isotropic etching in the gas diffusion space 22a. Radio frequency power is then applied to the gas ejection head 22. As a consequence, the gas mixture 64 for isotropic etching supplied to the gas diffusion space 22a is transformed into a plasma, and the resulting plasmatic etching gas 64 for isotropic etching is supplied for a certain period of time (for example, five seconds or longer and seven seconds or shorter) to the side of the front surface 11a of the workpiece 11. As a consequence, isotropic plasma etching is applied to the workpiece 11. It is to be noted that no radio frequency power is applied to the electrode 16 (see FIG. 2) in the isotropic etching substep S13. Isotropic plasma etching is hence applied to the workpiece 11. As a result, the bottoms of the cut grooves 19 and their vicinities are removed, so that the cut grooves 19 are caused to extend toward the side of the back surface 11b of the workpiece 11.

Subsequently, the above-described protective film application substep S11, the anisotropic etching substep S12, and the isotropic etching substep S13 are repeated until the cut grooves 19 reach the back surface 11b of the workpiece 11 (“NO” in the substep S14). When the cut grooves 19 reach the back surface 11b of the workpiece 11, and the workpiece 11 is divided along the scribe lines 13 (“YES” in the substep S14), the plasma etching step S3 is completed.

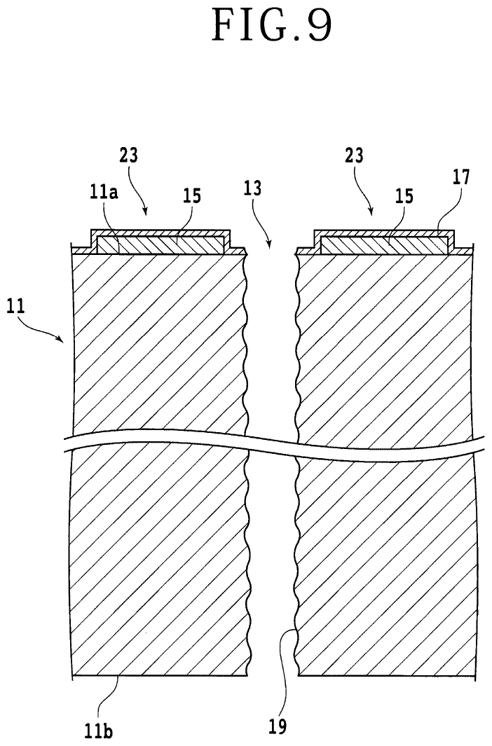

FIG. 9 is a fragmentary cross-sectional view depicting the workpiece 11 after the plasma etching step S3. After the plasma etching step S3 has been completed, the workpiece 11 has been removed along the scribe lines 13, and hence divided into a plurality of chips (device chips) 23 individually including the devices 15. It is to be noted that the description has been made above regarding the example in which the workpiece 11 is divided by the Bosch process, and the details of the plasma etching to be applied to the workpiece 11 can appropriately be changed.

After the plasma etching step S3, the mask 17 is removed (mask removal step S4). The mask 17 is removed from the respective chips 23, for example, by applying an asking treatment to the mask 17. As a consequence, the front surface 11a and devices 15 of the workpiece 11 are exposed.

In the manufacturing method for chips according to this embodiment, the mask 17 formed on the workpiece 11 is patterned by causing the cutting blade 48 to cut into the mask 17 to remove the mask 17 along the scribe lines 13, as described above. This enables formation of a mask for plasma etching with an inexpensive cutting apparatus, instead of a costly laser processing apparatus or the like, thereby reducing the costs of plasma etching.

It is to be noted that the structure, method, and the like according to the above-described embodiment can be practiced with appropriate changes or modifications within the scope not departing from the object of the present invention.

### Example

A description will next be made regarding the results of an evaluation of workpieces processed by the method according to the above-described embodiments. In the evaluation, after a film formed on each workpiece and containing carbon fluoride was divided along scribe lines by cutting it with a cutting blade (mask forming step S1, cutting step S2), plasma etching was applied to the workpiece (plasma etching step S3). By observing the workpiece after the plasma etching, confirmation was made on whether the film with the carbon fluoride contained therein appropriately functioned as a mask for plasma etching.

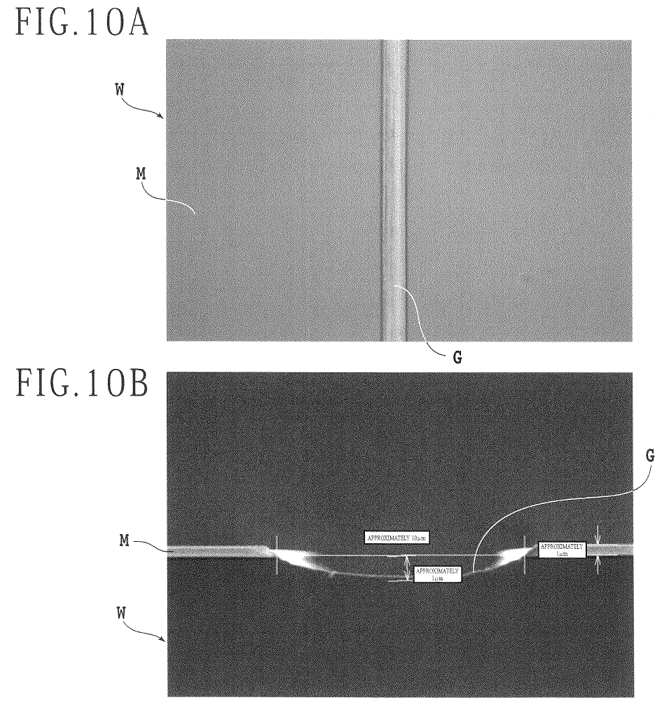

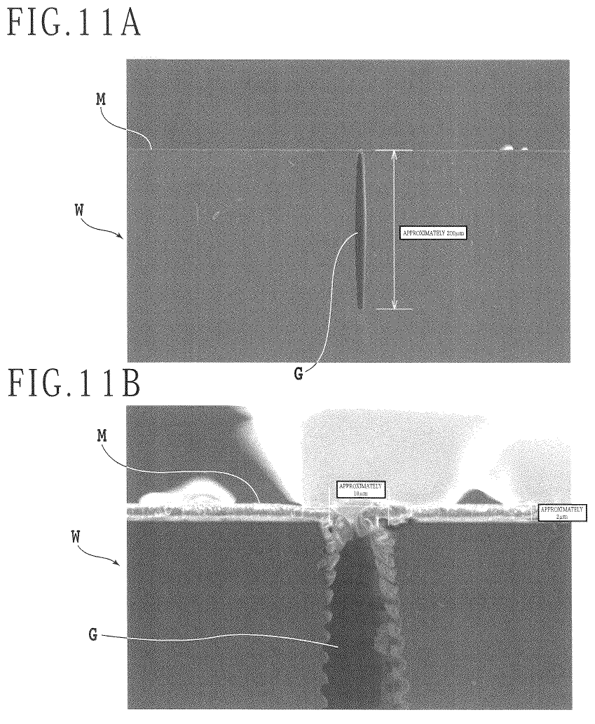

As the workpieces, wafers W (see FIGS. 10A to 11B) of single crystal silicon were used. In the mask forming step S1, a gas mixture with C₄F₈ and Ar contained therein was transformed into a plasma, and the resulting plasmatic gas was supplied to each wafer W, whereby a film with carbon fluoride contained therein (the mask M) was formed on a side of a front surface of the wafer W. It is to be noted that, for the formation of the mask, the plasma processing apparatus (see FIG. 2) was used, and the plasmatic gas was supplied for 60 seconds to the wafer W with no radio frequency power applied to the electrode 16 (see FIG. 2). As a result, the mask M was formed to have a thickness of approximately 1 μm on the side of the front surface of the wafer W.

The mask was next removed along the scribe lines by causing the cutting blade to cut into the mask (cutting step S2). The cutting blade (width: 12 μm) used in the cutting of the mask had a rounded tip end portion (see FIG. 5B). The processing feed rate was set to 10 mm/s, and the rotational speed of the spindle was set to 40,000 rpm. Further, the cut-in depth of the cutting blade was set such that the cutting blade was caused to cut into the wafer W at a depth of approximately 1 μm on the side of the front surface of the wafer W while splitting the mask M. After cutting the mask M, the wafer W was observed by imaging an upper surface and a cross-section thereof.

FIG. 10A is a micrograph depicting the side of the upper surface of the wafer W after the formation of the mask and the cut grooves. FIG. 10B is a micrograph depicting the cross-section of the wafer W after the formation of the mask and cut grooves. By causing the cutting blade to cut into the wafer W and the mask M, a strip-shaped cut groove G was formed along each scribe line, so that the mask M was split and at the same time, the upper surface of the wafer W was exposed inside the cut groove G. It is to be noted that the cutting blade was caused to cut into the mask M so as to allow only the rounded tip end portion thereof to come into contact with the mask M. As depicted in FIG. 10B, the rounded shape of the cutting blade is therefore reflected in the profile of the cut groove G, and therefore, the cut grooves G was formed including a curved inner surface that is convex toward a side of the wafer W. Further, as depicted in FIG. 10A, the mask M was split straight along the cut groove G, and no conspicuous peeling of the mask M was observed at opposite edge portions of the cut groove G. This is presumably attributable to a suppression of separation of the mask M owing to the contact of only the (rounded) tip end portion of the cutting blade with the mask M.

A plurality of gases in a plasma state were next supplied individually and successively to the wafer W through the mask M, and etching was applied to the wafer W. It is to be noted that the above-mentioned Bosch process was used in the etching of the wafer W, and the cut groove G was caused to extend toward a side of a back surface of the wafer W by repeating the protective film application substep S11, the anisotropic etching substep S12, and the isotropic etching substep S13 (see FIG. 7). After the cut groove G has extended to a certain extent, the cross-section of the wafer W was imaged and observed. It is to be noted that the plasma processing apparatus 2 (see FIG. 2) was used in the etching of the wafer W. Described specifically, in the protective film application substep S11, a C₄F₈-containing gas mixture was transformed into a plasma, and with no radio frequency power applied to the electrode 16, the plasmatic gas was supplied for six to eight seconds to the wafer W. Further, in the anisotropic etching substep S12, an SF₆-containing gas mixture was transformed into a plasma, and with radio frequency power (300 W) applied to the electrode 16, the plasmatic gas was supplied for three seconds to the wafer W. Furthermore, in the isotropic etching substep S13, the SF₆-containing gas mixture was transformed into a plasma, and with no radio frequency power applied to the electrode 16, the plasmatic gas was supplied for five to seven seconds to the wafer W.

FIG. 11A is a micrograph depicting a cross-section of the wafer M after the plasma etching. FIG. 11B is a micrograph depicting on an enlarged scale a cut groove G formed in the wafer W. When plasma etching was applied under the above-described processing conditions for predetermined periods of time, the cut groove G extended straight along a thickness direction of the wafer W, and the cut groove G was formed with a high aspect ratio (width: approximately 10 μm, depth: approximately 200 μm). From this result, it was confirmed that the mask M appropriately functioned as a mask for plasma etching, and the use of the mask M allowed the cut groove G to extend to the side of the back surface of the wafer W with a predetermined width maintained.

The present invention is not limited to the details of the above-described preferred embodiment. The scope of the invention is defined by the appended claims and all changes and modifications as fall within the equivalence of the scope of the claims are therefore to be embraced by the invention.

What is claimed is:

1. A manufacturing method of a plurality of chips, the method manufacturing the chips by dividing a workpiece that is defined into a plurality of regions by scribe lines, comprising:
a mask forming step of forming a mask by supplying a plasmatic deposition gas to a side of a front surface or a side of a back surface of the workpiece;
a cutting step of forming cut grooves, with the mask being removed along the scribe lines, by causing a cutting blade to cut into the workpiece at a predetermined cut-in depth along the scribe lines on the side of a surface on which the mask has been formed; and
a plasma etching step of removing the workpiece along the scribe lines to divide the workpiece into the chips by applying plasma etching to the workpiece while supplying a plasmatic etching gas to the side of the surface of the workpiece in which the cut grooves have been formed.

2. The manufacturing method according to claim 1, wherein
the cutting blade has a tip end portion having a width tapering toward a tip end, and
in the cutting step, the cutting blade is caused to cut into the mask such that only the tip end portion comes into contact with the mask.

3. The manufacturing method according to claim 1, wherein
in the cutting step, the cut-in depth of the cutting blade is set to smaller than 10 μm.

4. The manufacturing method according to claim 1, wherein
in the plasma etching step, the workpiece is divided into the chips along the scribe lines by repeating:
a protective film application substep of applying a protective film to the cut grooves by supplying a plasmatic deposition gas to the side of the surface of the workpiece in which the cut grooves have been formed;
an anisotropic etching substep of, after the protective film application substep, removing portions of the protective film covering corresponding bottoms of the cut grooves, through anisotropic plasma etching of the protective film by supplying a plasmatic gas for anisotropic etching to the cut grooves; and
an isotropic etching substep of, after the anisotropic etching substep, subjecting the bottoms of the cut grooves to isotropic plasma etching by supplying a plasmatic gas for isotropic etching to the cut grooves.

5. The manufacturing method according to claim 1, further comprising:
a mask removal step of removing the mask after the plasma etching step.
